(19) United States
(12) Patent Application Publication
(10) Pub. No.: US 2025/0359223 A1
(43) Pub. Date: Nov. 20, 2025

(54) Strain Elements in Metallic Source-Drain Architecture

(71) Applicant: Applied Materials, Inc., Santa Clara, CA (US)

(72) Inventors: Nicolas Louis BREIL, San Jose, CA (US); Yan ZHANG, Westford, MA (US)

(21) Appl. No.: 18/664,830

(22) Filed: May 15, 2024

(51) Int. Cl. H01L 29/08; H01L 21/822; H01L 21/8238; H01L 27/06; H01L 27/092; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 84/0167; H10D 84/017; H10D 84/038; H10D 84/856; H10D 88/00; H10D 88/01

(57) ABSTRACT

A method leverages compressive stress forces in forming a source-drain for a stacked nanosheet structure. The method may include forming an epitaxial growth layer on each of a plurality of channels of the stacked nanosheet structure where the channels are a silicon-based material and where the channels are separated by inner spacers of a dielectric material, stopping the epitaxial growth process prior to a crystal structure of one of the epitaxial growth layers on one channel of the stacked nanosheet structure merging into another crystal structure of any other one of the epitaxial growth layers on another channel of the stacked nanosheet structure or merging into surfaces of the inner spacers, and forming a compressive stress material on the plurality of epitaxial growth layers. In some embodiments, the compressive stress material fills the source-drain cavity and in other embodiments, a metal fill with compressive stress fills the source-drain cavity.

### FIELD

Embodiments of the present principles generally relate to semiconductor processing of semiconductor substrates.

### BACKGROUND

Stacked nanosheet structures may be used in semiconductor devices such as horizontal gate-all-around (GAA) and complementary field effect transistors (CFETs). hGAA and CFET devices may be the next steps in the evolution of transistors, respectively. The stacked nanosheet structures form channels in the hGAA and CFET devices and interface directly with source-drains that are connected to contacts. A gate permits the control of current that flows from the contacts into the source-drains and through the channels. The inventors have observed that defects within the source-drain material may cause the current flow through the channels to slow down, reducing performance of the devices.

Accordingly, the inventors have provided methods and architectures for improving the current flow through the channel area of stacked nanosheet devices.

### SUMMARY

Methods and architectures for providing compressive forces on a channel area in a stacked nanosheet structure using source-drains are provided herein.

In some embodiments, a method for forming a source-drain for a stacked nanosheet structure may comprise forming an epitaxial growth layer on each of a plurality of channels of the stacked nanosheet structure using an epitaxial growth process to form a plurality of epitaxial growth layers, wherein a material of the plurality of channels is a silicon-based material and wherein the plurality of channels are separated by inner spacers of a dielectric material, stopping the epitaxial growth process prior to a crystal structure of one of the plurality of epitaxial growth layers on one channel of the stacked nanosheet structure merging into another crystal structure of any other one of the plurality of epitaxial growth layers on another channel of the stacked nanosheet structure or merging into surfaces of the inner spacers, and forming a compressive stress material on the plurality of epitaxial growth layers.

In some embodiments, the method may further include a compressive stress material that fills a remaining portion of a source-drain cavity, a compressive stress material that is a selectively formed tin germanium (SnGe) epitaxial material, a silicide contact layer that is formed on the compressive stress material, a contact that is formed on the silicide contact layer, a compressive stress material that is a layer on each of the plurality of epitaxial growth layers, a layer of the compressive stress material that has a thickness of greater than zero to approximately 3 nm, a compressive stress material that is selectively formed on the plurality of epitaxial growth layers, a compressive stress material that is a tin germanium (SnGe) epitaxial layer, a compressive stress material that is formed by tin (Sn) implantation and a subsequent anneal process and where the Sn implantation uses an ion implantation process, a plasma doping process, or a gas phase doping process, a silicide contact layer that is formed on the compressive stress material, a metal fill material with a compressive stress that fills a remaining portion of a source-drain cavity, a contact that is formed on the metal fill material, a plurality of epitaxial growth layers that is silicon germanium (SiGe) with a boron (B) dopant, a silicon-based material of the plurality of channels that is silicon germanium (SiGe), and/or each of the plurality of epitaxial growth layers has a thickness of approximately 4 nm to approximately 10 nm.

In some embodiments, a source-drain for a stacked nanosheet structure may comprise a stack of two or more channels of the stacked nanosheet structure where the two or more channels are separated by inner spacers of a dielectric material, an epitaxial growth layer formed on each of the two or more channels of the stacked nanosheet structure where a crystal structure of the epitaxial growth layer does not merge into any other crystal structure of any other epitaxial growth layer or into surfaces of the inner spacers, and a compressive stress material on each epitaxial growth layer.

In some embodiments, the source-drain may further include a compressive stress material that fills a remaining portion of a source-drain cavity or a compressive stress material that is a layer on each epitaxial growth layer and a metal fill material with a compressive stress that fills a remaining portion of a source-drain cavity, and/or a compressive stress material that is tin germanium (SnGe) epitaxial material.

In some embodiments, a non-transitory, computer readable medium having instructions stored thereon that, when executed, cause a method for forming a source-drain for a stacked nanosheet structure to be performed, the method may comprise forming an epitaxial growth layer on each of a plurality of channels of the stacked nanosheet structure using an epitaxial growth process to form a plurality of epitaxial growth layers where a material of the plurality of channels is a silicon-based material and where the plurality of channels are separated by inner spacers of a dielectric material, stopping the epitaxial growth process prior to a crystal structure of one of the plurality of epitaxial growth layers on one channel of the stacked nanosheet structure merging into another crystal structure of any other one of the plurality of epitaxial growth layers on another channel of the stacked nanosheet structure or merging into surfaces of the inner spacers, and forming a compressive stress material on the plurality of epitaxial growth layers.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming a source-drain for a stacked nanosheet structure in accordance with some embodiments of the present principles.

FIG. 2 depicts a cross-sectional view of a stacked nanosheet structure with source-drain cavities in accordance with some embodiments of the present principles.

FIG. 3 depicts a cross-sectional view of forming epitaxial growth layers on channels of a stacked nanosheet structure in accordance with some embodiments of the present principles.

FIG. 4 depicts a cross-sectional view of epitaxial growth layers at a stopping point prior to crystal structure merging in accordance with some embodiments of the present principles.

FIG. 5 depicts a cross-sectional view of an embodiment with a source-drain cavity filled with a compressive stress material in accordance with some embodiments of the present principles.

FIG. 6 depicts a cross-sectional view of a silicide contact layer formed on the compressive stress material and a contact formed on the silicide contact layer in accordance with some embodiments of the present principles.

FIG. 7 depicts a cross-sectional view of another embodiment with a compressive stress material formed as a layer on the epitaxial growth layers in accordance with some embodiments of the present principles.

FIG. 8 depicts a cross-sectional view of a silicide contact layer formed on a compressive stress material which is formed as a layer on the epitaxial growth layers in accordance with some embodiments of the present principles.

FIG. 9 depicts a cross-sectional view of a metal fill material filling a source-drain cavity with a silicide contact layer formed on a compressive stress material which is formed as a layer on the epitaxial growth layers in accordance with some embodiments of the present principles.

FIG. 10 depicts a cross-sectional view of a contact formed on a metal fill material of a source-drain in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and architectures provide compressive forces on a channel area of a horizontal gate-all-around (hGAA) or complementary field effect transistor (CFET) device and the like stacked nanosheet structures using stress engineering within the source-drains. Careful formation of the source-drains provides a substantial reduction in crystal structure dislocations of an epitaxially grown source-drain material. The dislocation-free epitaxial source-drain material preserves the compressive forces exerted by the source-drain material on the channel area of the devices, increasing current flow performance by at least 5% or more over traditionally formed source-drains. In some embodiments, the source-drain may be filled with a metal material to form a metallic source-drain that includes strain elements for providing compressive forces on the channels of the devices.

hGAA and CFET devices use one or more stacks of silicon-based nanosheets as channels that interface with source-drains at the edges of the nanosheets. The nanosheets are separated by inner spacers formed of a dielectric material. In traditional source-drain formation processes, the source-drain material is epitaxially grown on silicon-based surfaces such as the edges of each of the nanosheets, and the epitaxial growth on each nanosheet merges together with each other and into the surfaces of the inner spacers during the source-drain formation (epitaxial growth does not start on the dielectric material of the inner spacers but may merge into the dielectric material during source-drain formation). As the epitaxial growth from the silicon-based surfaces merge together and into the surfaces of the inner spacers, dislocations in the epitaxial crystal structure form in the source-drain material. The inventors have found that the dislocations relieve stress within the source-drain material (e.g., silicon germanium doped with boron and the like), and the source-drain material will no longer exert a compressive force on the channels (nanosheets). Without the compressive force, the carrier mobility within the channels is reduced, affecting the performance of the devices. The inventors have discovered that by reducing dislocations and by replacing some or all of the merged source-drain material with compressive stress materials, such as, but not limited to, a pure germanium (Ge) layer and/or a germanium layer doped with tin (Sn) and the like, performance of the devices can be improved. In some embodiments, the Sn can be introduced by means of epitaxial growth or by means of ion implantation, plasma doping, or gas phase doping followed by annealing.

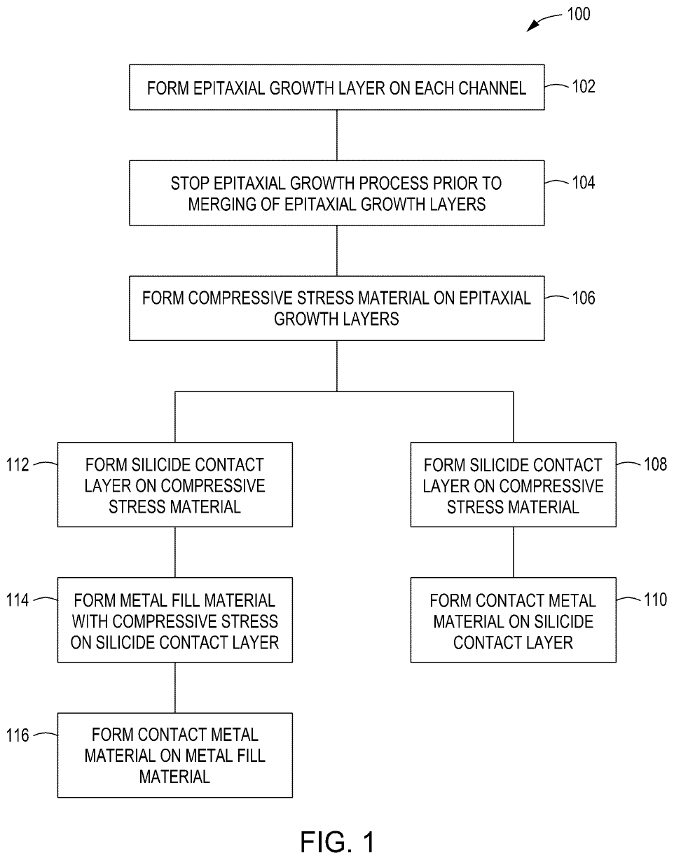

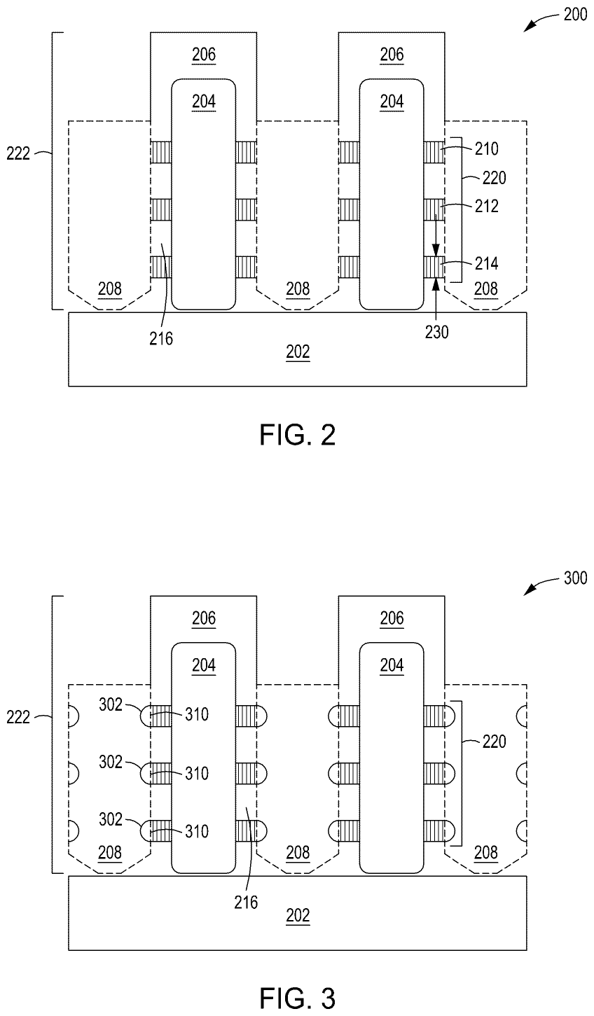

FIG. 1 is a method 100 for forming a source-drain of a stacked nanosheet structure. The present methods are not limited by the type of device structure in FIG. 2. For example, the device in FIG. 2 may be a CFET with two stacked nanosheet structures stacked one on the other in a vertical direction and the like. The device structure 222 of FIG. 2 is used as an example in the following scenarios for the sake of brevity. In the example of FIG. 2, the device structure 222 has a gate 204 surrounding the nanosheets or channels 220 with a gate cap 206 and source-drain cavities 208 (the cavities are openings that expose the edges of the channels 220 in which a source-drain can be formed) on each side of the channels 220, all of which are formed on a substrate 202. The channels 220, in the example, include a first channel 210, a second channel 212, and a third channel 214 which may be formed, in some embodiments, of a silicon germanium (SiₓGe₁₋ₓ) material. The number of channels in a structure may be more or less than the example of FIG. 2. In some embodiments, X may be from approximately 0.85 to approximately 0.95. In some embodiments the SiGe may be further doped with a dopant such as boron and the like. In some embodiments, the channels may have a thickness 230 of approximately 5 nm to approximately 10 nm. In some embodiments, the thickness may be approximately 6 nm. The channels may be separated by inner spacers 216 composed of a dielectric material. In some embodiments, the inner spacers 216 may be SiC, SiOC, or SiOCN, and the like. For the sake of brevity, the formation of the device structure 222 as depicted in the view 200 of FIG. 2 is not discussed and is used as a starting point for the present methods. In other words, the source-drain cavities 208 and channels 220 have been completed as well as some or all of the gate cap 206 and the gate 204 and the like prior to the performing of the present methods.

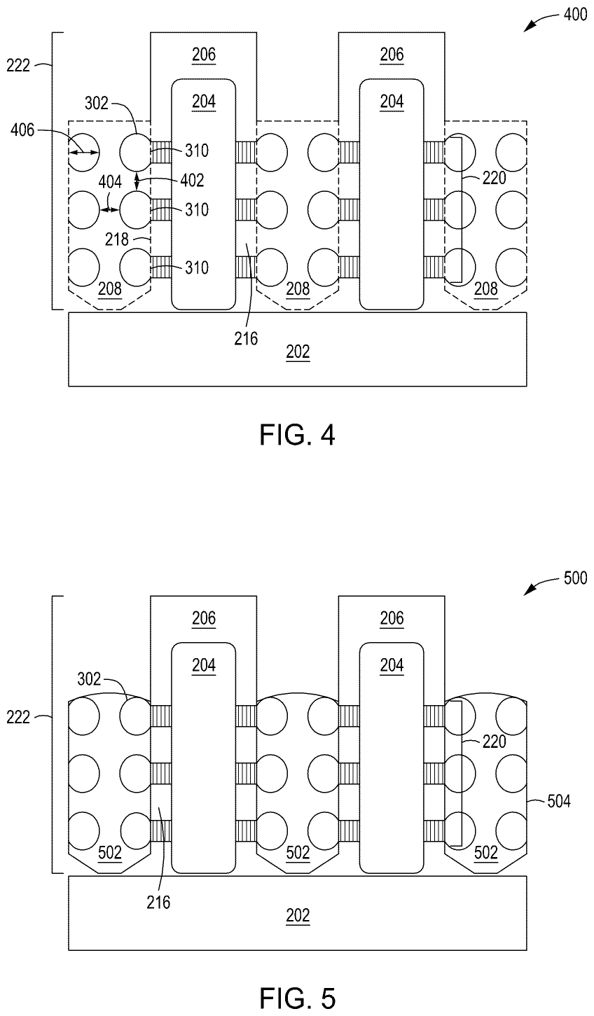

In block 102, an epitaxial growth layer 302 is formed on the edges 310 of each of the channels 220 as depicted in a view 300 of FIG. 3. In some embodiments, the epitaxial growth layer 302 is formed of a high-quality epitaxial silicon germanium (SiₓGe₁₋ₓ) material with or without a boron dopant. The epitaxial growth process is a selective process that uses the exposed edges of the channels 220 as a seed for selectively starting the epitaxial growth. In block 104, the epitaxial growth process of the epitaxial growth layer 302 is stopped prior to the merging of the crystal structure of the epitaxial growth layer 302 with any other epitaxial growth layer or with the surfaces 218 of the inner spacers 216 as depicted in a view 400 of FIG. 4. In some embodiments, the width 406 of the epitaxial growth layer 302 may be approximately 4 nm to approximately 10 nm. A distance 402 between epitaxial growth layers of adjacent channels may be any distance, including zero, as the epitaxial growth layers may touch each other or touch the surfaces 218 of the inner spacers 216 so long as the crystal structures of each of the epitaxial growth layers do not merge into each other or into the surfaces 218 of the inner spacers 216. The merging of the crystal structures into each other or the surfaces 218 of the inner spacers 216 causes dislocations as discussed above which leads to diminished compressive forces applied to the channels 220. In some embodiments, a gap 404 may be included to allow for subsequent processes as described below. In some embodiments, the gap 404 may have sufficient size to incorporate one or more layers on the epitaxial growth layer 302 and/or sufficient size to allow for a metal gap fill in the source-drain cavities 208.

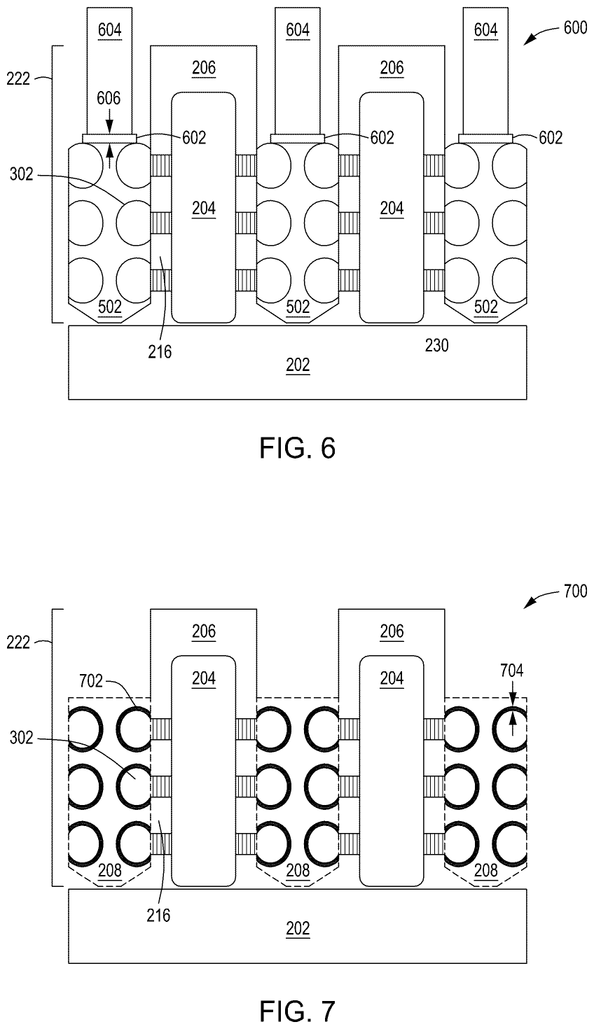

In block 106, a compressive stress material is formed on the epitaxial growth layers 302. In some embodiments, the compressive stress material is formed as a layer on or into the epitaxial growth layers 302 as discussed below for blocks 106 and 112-116 and FIGS. 7-10. In some embodiments, the compressive stress material is a gap fill material that fills the remaining portions of the source-drain cavities 208 as discussed presently for blocks 106-110 and FIGS. 5 and 6. In the example of view 500 of FIG. 5, the compressive stress material 502 is deposited in a gap fill process in the remaining portion of the source-drain cavities 208 to form a source-drain 504. In some embodiments, the gap fill process completely fills the source-drain cavity with the compressive stress material 502. The compressive stress material 502 may be any material that produces compressive forces on the channels 220. In some embodiments, the compressive stress material 502 may be tin germanium (SnGe) or pure germanium (Ge) and the like. In block 108, a silicide contact layer 602 is formed on the compressive stress material 502 as depicted in a view 600 of FIG. 6. In some embodiments, the silicide contact layer 602 may be formed of silicide based on titanium, nickel, platinum, or tantalum and the like. The silicide contact layer 602 may be formed using an atomic layer deposition, a chemical vapor deposition, or a physical vapor deposition process, and the like. The thickness 606 of the silicide contact layer 602 may be from greater than zero to approximately 1 nm. In block 110, contact metal material 604 is formed on the silicide contact layer 602 as depicted in the view 600 of FIG. 6. In some embodiments, the contact metal material 604 may be formed by a gapfill process and the like.

In an alternative embodiment, in block 106, the compressive stress material 702 is formed as a layer on or into the epitaxial growth layers 302 as depicted in a view 700 of FIG. 7. In some embodiments, the compressive stress material 702 is formed using an implantation process followed by an anneal process to form a layer of compressive stress material 702 into the surface of the epitaxial growth layer 302. For example, but not limited to, tin (Sn) may be implanted into the surface of the epitaxial growth layer 302. The implantation may be accomplished using a gas-based doping or a plasma-based doping process followed by annealing or by an ion implantation process and the like. In some embodiments, the compressive stress material 702 may be selectively deposited on the surface of the epitaxial growth layer 302. For example, but not limited to, a selective tin germanium (SnGe) epitaxial layer may be grown on the surface of the epitaxial growth layer 302. A thickness 704 of the compressive stress material 702 is dependent on the dopant concentration epitaxially grown on the surface or on the dopant concentration of the implantation into the surface (e.g., amount of Sn, etc.). The higher the concentration of the implantation, the thinner the compressive stress material 702. In some embodiments, the thickness 704 on or into the surface of the epitaxial growth layer 302 may be greater than zero to approximately 3 nm.

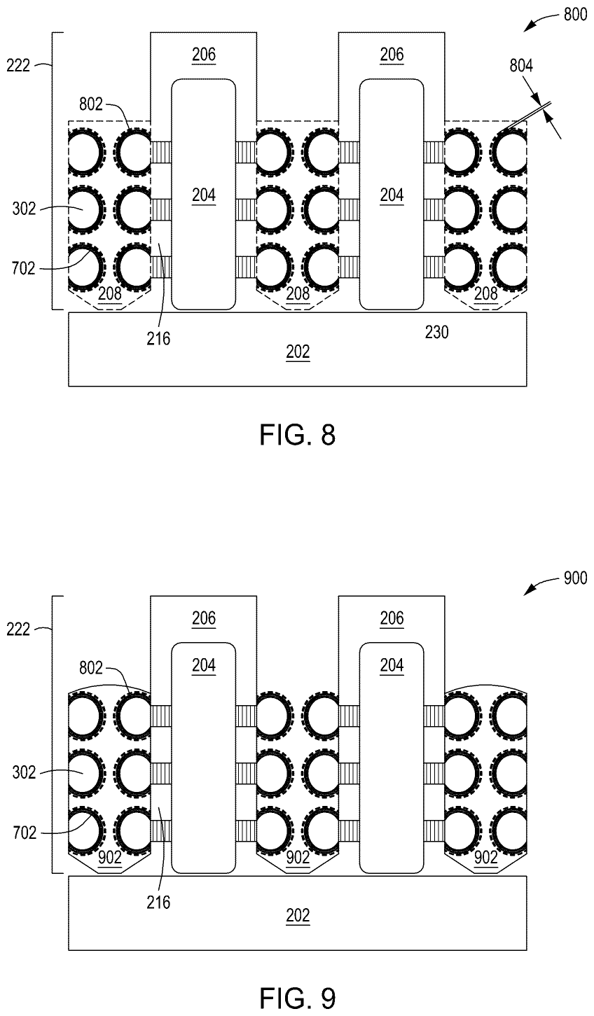

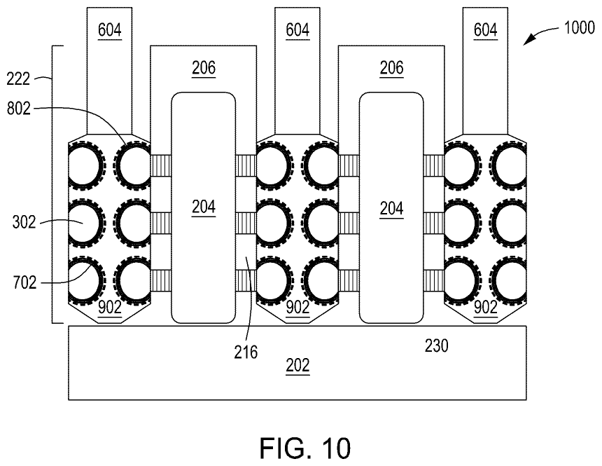

In block 112 of the alternative approach, a silicide contact layer 802 is then formed on the layer of compressive stress material 702 as depicted in a view 800 of FIG. 8. In some embodiments, the silicide contact layer 802 may be formed of silicide based on titanium, nickel, platinum, or tantalum, and the like. The silicide contact layer 802 may be formed using an atomic layer deposition, a chemical vapor deposition, or a physical vapor deposition process and the like. The thickness 804 of the silicide contact layer 802 may be from greater than zero to approximately 1 nm. In block 114, a metal fill material 902 with compressive stress is formed on the silicide contact layer 802 by filling the remaining portions of the source-drain cavity 208 to form the source-drain as depicted in a view 900 of FIG. 9. In some embodiments, the metal fill material 902 may completely fill the source-drain cavity 208. In some embodiments, the metal fill material 902 may be, for example but not limited to, titanium or titanium nitride and the like deposited by atomic layer deposition, chemical vapor deposition, or physical vapor deposition processes to form a metallic source-drain with strain elements. In block 116, a contact metal material 604 is then formed on the metal fill material 902 as depicted in a view 1000 of FIG. 10.

The embodiment in FIG. 6 is less complex and easier to integrate into existing manufacturing processes. The embodiment of FIG. 10 has greater contact area and less contact resistance but with higher manufacturing complexity and a higher level of integration effort is required. Either process can be tuned to adjust the compressive force on the channels. In some embodiments, a compressive force of approximately 200 megapascal (MPa) to approximately 1 gigapascal (GPa) can be exerted on the channels using either process. The increased compressive force increases the mobility within the channels to increase current flow to 5% or greater over traditional source-drains.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming a source-drain for a stacked nanosheet structure, comprising:
forming an epitaxial growth layer on each of a plurality of channels of the stacked nanosheet structure using an epitaxial growth process to form a plurality of epitaxial growth layers, wherein a material of the plurality of channels is a silicon-based material and wherein the plurality of channels are separated by inner spacers of a dielectric material;
stopping the epitaxial growth process prior to a crystal structure of one of the plurality of epitaxial growth layers on one channel of the stacked nanosheet structure merging into another crystal structure of any other one of the plurality of epitaxial growth layers on another channel of the stacked nanosheet structure or merging into surfaces of the inner spacers; and
forming a compressive stress material on the plurality of epitaxial growth layers.

2. The method of claim 1, wherein the compressive stress material fills a remaining portion of a source-drain cavity.

3. The method of claim 2, wherein the compressive stress material is a selectively formed tin germanium (SnGe) epitaxial material.

4. The method of claim 2, wherein a silicide contact layer is formed on the compressive stress material.

5. The method of claim 4, wherein a contact is formed on the silicide contact layer.

6. The method of claim 1, wherein the compressive stress material is a layer on each of the plurality of epitaxial growth layers.

7. The method of claim 6, wherein the layer of the compressive stress material has a thickness of greater than zero to approximately 3 nm.

8. The method of claim 6, wherein the compressive stress material is selectively formed on the plurality of epitaxial growth layers.

9. The method of claim 8, wherein the compressive stress material is a tin germanium (SnGe) epitaxial layer.

10. The method of claim 6, wherein the compressive stress material is formed by tin (Sn) implantation and a subsequent anneal process and wherein the Sn implantation uses an ion implantation process, a plasma doping process, or a gas phase doping process.

11. The method of claim 6, wherein a silicide contact layer is formed on the compressive stress material.

12. The method of claim 11, wherein a metal fill material with a compressive stress fills a remaining portion of a source-drain cavity.

13. The method of claim 12, wherein a contact is formed on the metal fill material.

14. The method of claim 1, wherein the plurality of epitaxial growth layers is silicon germanium (SiGe) with a boron (B) dopant.

15. The method of claim 1, wherein the silicon-based material of the plurality of channels is silicon germanium (SiGe).

16. The method of claim 1, wherein each of the plurality of epitaxial growth layers has a thickness of approximately 4 nm to approximately 10 nm.

17. A source-drain for a stacked nanosheet structure, comprising:
a stack of two or more channels of the stacked nanosheet structure, wherein the two or more channels are separated by inner spacers of a dielectric material;
an epitaxial growth layer formed on each of the two or more channels of the stacked nanosheet structure, wherein a crystal structure of the epitaxial growth layer does not merge into any other crystal structure of any other epitaxial growth layer or into surfaces of the inner spacers; and
a compressive stress material on each epitaxial growth layer.

18. The source-drain for the stacked nanosheet structure of claim 17, wherein the compressive stress material fills a remaining portion of a source-drain cavity or wherein the compressive stress material is a layer on each epitaxial growth layer and a metal fill material with a compressive stress fills a remaining portion of a source-drain cavity.

19. The source-drain for the stacked nanosheet structure of claim 17, wherein the compressive stress material is tin germanium (SnGe) epitaxial material.

20. A non-transitory, computer readable medium having instructions stored thereon that, when executed, cause a method for forming a source-drain for a stacked nanosheet structure to be performed, the method comprising:
forming an epitaxial growth layer on each of a plurality of channels of the stacked nanosheet structure using an epitaxial growth process to form a plurality of epitaxial growth layers, wherein a material of the plurality of channels is a silicon-based material and wherein the plurality of channels are separated by inner spacers of a dielectric material;
stopping the epitaxial growth process prior to a crystal structure of one of the plurality of epitaxial growth layers on one channel of the stacked nanosheet structure merging into another crystal structure of any other one of the plurality of epitaxial growth layers on another channel of the stacked nanosheet structure or merging into surfaces of the inner spacers; and
forming a compressive stress material on the plurality of epitaxial growth layers.
